(19) United States
(12) Patent Application Publication
(10) Pub. No.: US 2024/0313147 A1
(43) Pub. Date: Sep. 19, 2024

(54) LIGHT EMITTING ELEMENT AND PRODUCTION METHOD THEREFOR

(71) Applicant: TOYODA GOSEI CO., LTD., Kiyosu-shi (JP)

(72) Inventors: Koji OKUNO, Kiyosu-shi (JP); Masaki OYA, Kiyosu-shi (JP)

(21) Appl. No.: 18/605,397

(22) Filed: Mar. 14, 2024

(30) Foreign Application Priority Data
Mar. 16, 2023 (JP) 2023-041521

(51) Int. Cl. H01L 33/00; H01L 33/06; H01L 33/32

(52) U.S. Cl. CPC H01L 33/0016; H01L 33/06; H01L 33/32

(57) ABSTRACT

In a flip-chip type light emitting element, light emitted from the second active layer causes interference between light directed toward the substrate and light directed toward the p electrode and reflected by the p electrode, and the interference is controlled based on a thickness of the p layer, light emitted from the first active layer causes interference between light directed toward the substrate and the light directed toward the p electrode and reflected by the p electrode, and the interference is controlled based on the thickness of the p layer and a thickness the middle layer, and the thickness of the p layer and the thickness of middle layer are set such that at least one of the light emitted from the first active layer or the light emitted from the second active layer is amplified by the interference.

### CROSS-REFERENCE TO RELATED APPLICATION

This application is based on and claims priority under 35 USC 119 from Japanese Patent Application No. 2023-041521 filed on Mar. 16, 2023.

### TECHNICAL FIELD

The present invention relates to a light emitting element and a production method therefor.

### BACKGROUND ART

As a light emitting element that emits white light, there is known a structure in which active layers emitting blue, green, and red light are sequentially stacked, and the respective layers emit light at the same time produce white light. For example, Jpn. J. Phys. 52 08JG02 2013, J. Appl. Phys. 112.083101 (2012), and AIP Advances 5, 057168 (2015) are known.

### SUMMARY OF INVENTION

However, with such a light emitting element, it is not possible to emit light of respective colors at the same time and to control an intensity of each light emission. In addition, light emission efficiency is reduced in the order of blue, green, and red, making it difficult to control a balance of a light output.

The present invention has been made in view of such a background, and an object thereof is to provide a light emitting element in which a plurality of active layers are sequentially stacked, respective active layers emit light at the same time, and a light output of each light emission can be controlled.

An aspect of the invention is directed to a light emitting element, which is a flip-chip type light emitting element comprising a group III nitride semiconductor, including:
a substrate;
an n layer that is provided over the substrate and comprises an n-type group III nitride semiconductor;
a first active layer that is provided over the n layer and has a predetermined emission wavelength;
a middle layer that is provided over the first active layer and comprises a group III nitride semiconductor having an n-type impurity concentration of 1×10¹⁸ cm⁻³ or less;
a second active layer that is provided over the middle layer and has an emission wavelength different from the emission wavelength of the first active layer;
a p layer that is provided over the second active layer and comprises a p-type group III nitride semiconductor; and
a p electrode that is provided over the player and is configured to reflect light, wherein
light emitted from the second active layer causes interference between light directed toward the substrate and light directed toward the p electrode and reflected by the p electrode, and the interference is controlled based on a thickness of the player,
light emitted from the first active layer causes interference between light directed toward the substrate and the light directed toward the p electrode and reflected by the p electrode, and the interference is controlled based on the thickness of the p layer and a thickness the middle layer, and
the thickness of the p layer and the thickness of middle layer are set such that at least one of the light emitted from the first active layer or the light emitted from the second active layer is amplified by the interference.

An another aspect of the invention is directed to a method for producing a light emitting element which is a flip-chip type light emitting element comprising a group III nitride semiconductor, including:
an n layer forming step of forming an n layer comprising an n-type group III nitride semiconductor over a substrate;
a first active layer forming step of forming a first active layer having a predetermined emission wavelength over the n layer;
a middle layer forming step of forming a middle layer comprising a group III nitride semiconductor having an n-type impurity concentration of 1×10¹⁸ cm⁻³ or less over the first active layer;
a second active layer forming step of forming a second active layer having an emission wavelength different from the emission wavelength of the first active layer over the middle layer;
a p layer forming step of forming a p layer comprising a p-type group III nitride semiconductor over the second active layer; and
a p electrode forming step of forming, over the p layer, a p electrode configured to reflect light, wherein
light emitted from the second active layer causes interference between light directed toward the substrate and light directed toward the p electrode and reflected by the p electrode, and the interference is controlled based on a thickness of the p layer,
light emitted from the first active layer causes interference between light directed toward the substrate and light directed toward the p electrode and reflected by the p electrode, and the interference is controlled based on the thickness of the p layer and a thickness the middle layer, and
the thickness of the p layer and the thickness of middle layer are set such that at least one of the light emitted from the first active layer or the light emitted from the second active layer is amplified by the interference.

According to the above aspects, since the middle layer is provided between the first active layer and the second active layer, and the n-type impurity concentration in the middle layer is 1×10¹⁸ cm⁻³ or less, the first active layer and the second active layer can emit light at the same time. In addition, each light emission can be controlled by interference of the light.

### BRIEF DESCRIPTION OF DRAWINGS

FIG. 1 is a diagram showing a configuration of a light emitting element according to a first embodiment, and is a cross-sectional view taken in a plane perpendicular to a substrate.

FIG. 2 is a diagram showing an equivalent circuit of the light emitting element according to the first embodiment.

FIG. 3 is a diagram showing a process for producing the light emitting element according to the first embodiment.

FIG. 4 is a diagram showing the process for producing the light emitting element according to the first embodiment.

### DETAILED DESCRIPTION OF THE INVENTION

A light emitting element is a flip-chip type light emitting element made of a group III nitride semiconductor. The light emitting element includes: a substrate; an n layer provided on the substrate and made of an n-type group III nitride semiconductor; a first active layer provided on the n layer and having a predetermined emission wavelength; a middle layer provided on the first active layer and made of a group III nitride semiconductor having an n-type impurity concentration of 1×10¹⁸ cm⁻³ or less; a second active layer provided on the middle layer and having an emission wavelength different from the emission wavelength of the first active layer; a p layer provided on the second active layer and made of a p-type group III nitride semiconductor; and a p electrode provided on the p layer and configured to reflect light. Light emitted from the second active layer interferes between light directed toward the substrate and light directed toward the p electrode and reflected by the p electrode, and the interference is controlled based on a thickness of the p layer, light emitted from the first active layer interferes between light directed toward the substrate and the light directed toward the p electrode and reflected by the p electrode, and the interference is controlled based on the thickness of the p layer and a thickness the middle layer, and the thickness of the p layer and the thickness of middle layer are set such that at least one of the light emitted from the first active layer or the light emitted from the second active layer is amplified by the interference.

In the above light emitting element, the middle layer may be made of a group III nitride semiconductor containing In.

In the above light emitting element, the emission wavelength of the second active layer may be longer than the emission wavelength of the first active layer, and the second active layer may have a structure in which a strain relaxation layer having a quantum well structure and a thickness of a well layer adjusted so as not to emit light, and a light emitting layer having a quantum well structure and configured to emit light are sequentially stacked. A wavelength corresponding to band edge energy of the well layer of the strain relaxation layer may be set to be shorter than an emission wavelength of the light emitting layer. The thickness of the p layer, the thickness of the middle layer, and a thickness of the strain relaxation layer may be set such that at least one of the light emitted from the first active layer or the light emitted from the second active layer is amplified by the interference.

In the above light emitting element, the middle layer may have a structure in which a non-doped layer made of a non-doped group III nitride semiconductor and an n layer made of a n-type group III nitride semiconductor are sequentially stacked.

A method for producing a light emitting element is a method for producing a flip-chip type light emitting element made of a group III nitride semiconductor. The method for producing a light emitting element includes: an n layer forming step of forming an n layer made of an n-type group III nitride semiconductor on a substrate; a first active layer forming step of forming a first active layer having a predetermined emission wavelength on the n layer; a middle layer forming step of forming a middle layer made of a group III nitride semiconductor having an n-type impurity concentration of 1×10¹⁸ cm⁻³ or less on the first active layer; a second active layer forming step of forming a second active layer having an emission wavelength different from the emission wavelength of the first active layer on the middle layer; a player forming step of forming a p layer made of a p-type group III nitride semiconductor on the second active layer; and a p electrode forming step of forming, on the p layer, a p electrode configured to reflect light. Light emitted from the second active layer interferes between light directed toward the substrate and light directed toward the p electrode and reflected by the p electrode, and the interference is controlled based on a thickness of the p layer, light emitted from the first active layer interferes between light directed toward the substrate and the light directed toward the p electrode and reflected by the p electrode, and the interference is controlled based on the thickness of the p layer and a thickness the middle layer, and the thickness of the p layer and the thickness of middle layer are set such that at least one of the light emitted from the first active layer or the light emitted from the second active layer is amplified by the interference.

In the above method for producing a light emitting element, the middle layer may be made of a group III nitride semiconductor containing In.

In the above method for producing a light emitting element, the emission wavelength of the second active layer may be longer than the emission wavelength of the first active layer, the second active layer may be formed by sequentially stacking a strain relaxation layer having a quantum well structure and a thickness of a well layer adjusted so as not to emit light, and a light emitting layer having a quantum well structure and configured to emit light, a wavelength corresponding to band edge energy of the well layer of the strain relaxation layer may be set to be shorter than an emission wavelength of the light emitting layer, and the thickness of the p layer, the thickness of the middle layer, and a thickness of the strain relaxation layer may be set such that at least one of the light emitted from the first active layer or the light emitted from the second active layer is amplified by the interference.

In the above method for producing a light emitting element, the middle layer may be formed by sequentially stacking a non-doped layer made of a non-doped group III nitride semiconductor and an n layer made of a n-type group III nitride semiconductor.

### First Embodiment

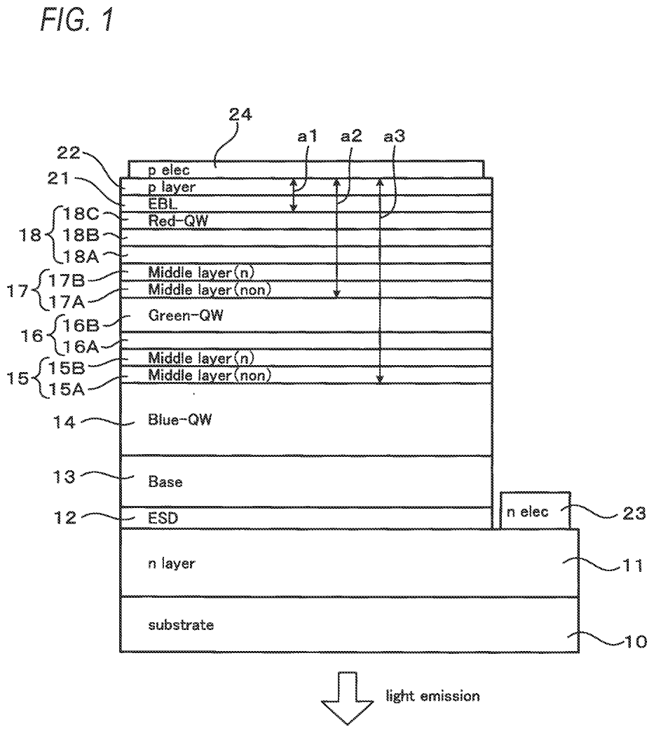

FIG. 1 is a diagram showing a configuration of a light emitting element according to a first embodiment. The light emitting element according to the first embodiment emits blue, green, and red light at the same time and emits white light by mixing the colors. In addition, the light emitting element according to the first embodiment is a flip-chip type that extracts light from a back surface of a substrate, and is mounted on a mounting substrate (not shown) in a face-down manner. Note that, in the first embodiment, one pixel has a structure of one chip, but a monolithic type may be used. That is, it may be a micro LED display element in which the element structure in the first embodiment is arranged in a matrix on the same substrate.

### 1. Configuration of Light Emitting Element

As shown in FIG. 1, the light emitting element according to the first embodiment includes a substrate 10, an n layer 11, an ESD layer 12, a base layer 13, a first active layer 14, a first middle layer 15, a second active layer 16, a second middle layer 17, a third active layer 18, an electron blocking layer 21, ap layer 22, an n electrode 23, and p electrode 24.

The substrate 10 is a growth substrate on which a group III nitride semiconductor is grown. For example, sapphire, Si, GaN, or ScAlMgO₄.

The n layer 11 is an n-type semiconductor layer provided on the substrate 10 via a low-temperature buffer layer or a high-temperature buffer layer (not shown). However, the buffer layer may be provided as necessary, and the buffer layer may not be provided when the substrate is GaN. The n layer 11 is, for example, n-GaN or n-AlGaN. A Si concentration is, for example, 1×10¹⁸ cm⁻³ to 100×10¹⁸ cm⁻³.

The ESD layer 12 is a semiconductor layer provided on the n layer 11, and is a layer provided to improve an electrostatic breakdown voltage. The ESD layer 12 may be provided as necessary and may be omitted. The ESD layer 12 is, for example, non-doped or lightly Si-doped GaN, InGaN, or AlGaN.

The base layer 13 is a semiconductor layer having a superlattice structure provided on the ESD layer 12, and is a layer for relaxing lattice strain in a semiconductor layer formed on the base layer 13. The base layer 13 may be provided as necessary and may be omitted. The base layer 13 is formed by alternately stacking group III nitride semiconductor thin films having different compositions (for example, two of GaN, InGaN, and AlGaN), and the number of pairs is, for example, 3 to 30. The base layer 13 may be non-doped or doped with Si by about 1×10¹⁷ cm⁻³ to 100×10¹⁷ cm⁻³. It is not necessary to have a superlattice structure as long as the strain can be relaxed. Any material may be used as long as a lattice constant difference is small at a hetero-interface with the first active layer 14. For example, an InGaN layer, an AlInN layer, or an AlGaIn layer may be used.

The first active layer 14 is a light emitting layer having an SQW or MQW structure provided on the base layer 13. An emission wavelength is blue and is 430 nm to 480 nm. The first active layer 14 has a structure in which a barrier layer made of AlGaN and a well layer made of InGaN are alternately stacked for 1 to 7 pairs. The number of pairs is more preferably 1 to 5, and still more preferably 1 to 3.

The first middle layer 15 is a semiconductor layer provided on the first active layer 14, and is positioned between the first active layer 14 and the second active layer 16. The first middle layer 15 is a layer provided to enable light emission from the first active layer 14 and light emission from the second active layer 16 to be separately controlled.

The first middle layer 15 has a structure in which a non-doped layer 15A and an n layer 15B are sequentially stacked from the first active layer 14. The non-doped layer 15A and the n layer 15B are made of the same material except for impurities. A reason why the n-side layer of the two first middle layers 15 is made non-doped is to improve carrier confinement in the first active layer 14 below the first middle layer 15.

The material of the first middle layer 15 is a group III nitride semiconductor containing In, and is preferably InGaN, for example. With a surfactant effect of In, roughness on a surface of the first middle layer 15 can be prevented and surface flatness can be improved. In addition, the lattice strain can be relaxed.

It is sufficient that an In composition (a molar ratio of In to all group III metals in the group III nitride semiconductor) of the first middle layer 15 is set to have a band gap in which light emitted from the first active layer 14 and the second active layer 16 is not absorbed. A preferred In composition is 10% or less, more preferably 5% or less, and still more preferably 2% or less. When the In composition is greater than 10%, the surface of the first middle layer 15 is rough. The In composition is any as long as it is greater than 0%, and may be at a doping level (a level that does not form a mixed crystal). For example, GaN having an In concentration of 1×10¹⁴ cm⁻³ or more and 1×10²² cm⁻³ or less.

The non-doped layer 15A is non-doped, and the n layer 15B is Si-doped. A Si concentration in the n layer 15B is 1×10¹⁸ cm⁻³ or less. Accordingly, red light, green light, and blue light can be emitted at the same time. The n layer 15B may be modulated and doped with Si, or there may be a non-doped region in a partial region of the n layer 15B.

A thickness of the first middle layer 15 is preferably 20 nm to 150 nm. When the thickness is more than 150 nm, the surface of the first middle layer 15 may be rough. It is more preferably 30 nm to 100 nm, and still more preferably 50 nm to 80 nm.

A thickness of the n layer 15B is preferably 10 nm or more. This is for independently controlling light emitting characteristics of each active layer.

The second active layer 16 has a structure in which a strain relaxation layer 16A and an SQW or MQW quantum well structure layer (light emitting layer) 16B are sequentially stacked. An emission wavelength of the quantum well structure layer 16B is green and is 510 nm to 570 nm. The quantum well structure layer 16B has a structure in which a barrier layer made of GaN and a well layer made of InGaN are alternately stacked for 1 to 7 pairs. The number of pairs is more preferably 1 to 5, and still more preferably 1 to 3. The number of pairs is preferably equal to or less than that of the first active layer 14, and more preferably less than that of the first active layer 14.

The strain relaxation layer 16A has an SQW structure in which a barrier layer and a well layer are sequentially stacked, and has a quantum well structure in which a thickness of the well layer is adjusted to be thin so as not to emit light. For example, when the thickness of the well layer is set to 1 nm or less, it is possible to prevent the well layer from emitting light. The barrier layer is AlGaN, and the well layer is InGaN. It is sufficient that a wavelength corresponding to band edge energy in the well layer of the strain relaxation layer 16A is shorter than the emission wavelength of the quantum well structure layer 16B, and is, for example, 400 nm to 460 nm when the emission wavelength is 500 nm to 560 nm. Preferably, the wavelength is 40 nm to 100 nm shorter than the emission wavelength of the quantum well structure layer 16B. In this case, a growth temperature for the strain relaxation layer 16A is 700° C. to 800° C.

The wavelength corresponding to the band edge energy in the well layer of the strain relaxation layer 16A may be equal to the emission wavelength of the first active layer 14. In this case, the strain relaxation layer 16A may be grown at a growth temperature same as that for the first active layer 14.

The band edge energy in the well layer of the strain relaxation layer 16A can be controlled based on the thickness of the well layer. That is, when the thickness of the well layer of the strain relaxation layer 16A is made sufficiently small, energy in a sub-band within the well increases and the band edge energy increases. Accordingly, the wavelength may be shorter than the emission wavelength of the quantum well structure layer 16B. The growth temperature is any, and the strain relaxation layer 16A may be grown at a growth temperature same as that for the quantum well structure layer 16B. Further, when the film thickness of the well layer of the strain relaxation layer 16A is made small, the energy in the sub-band further increases, and an energy difference with the barrier layer is smaller. That is, it is close to band edge energy in the barrier layer. As a result, it is difficult to confine carriers in the well layer of the strain relaxation layer 16A, making it difficult to emit light. Therefore, the well layer functions as a part of the barrier layer of the quantum well structure layer 16B, and at the same time, a strain relaxation effect can be obtained.

In this way, by forming the strain relaxation layer 16A having a well layer with worse carrier confinement than the well layer of the quantum well structure layer 16B, it is possible to form the strain relaxation layer 16A that does not emit light.

In short, it is sufficient that a material and a layer configuration of the strain relaxation layer 16A are set such that an effective lattice constant of the entire strain relaxation layer 16A is between a lattice constant of the first middle layer 15 and a lattice constant of the quantum well structure layer 16B, and the thickness of the well layer is set such that the strain relaxation layer 16A does not emit light.

The strain relaxation layer 16A may have an MQW structure in which a barrier layer and a well layer are stacked for 2 or more pairs, and it is preferable to have an SQW structure since the second active layer 16 is thick.

As described above, when the strain relaxation layer 16A is provided, strain in the quantum well structure layer 16B stacked thereon can be relaxed, and a crystal quality of the well layer of the quantum well structure layer 16B can be improved.

The second middle layer 17 is semiconductor layer provided on the second active layer 16, and is positioned between the second active layer 16 and the third active layer 18. The second middle layer 17 is provided for a reason same as that of the first middle layer 15, and is a layer provided to enable light emission from the second active layer 16 and light emission from the third active layer 18 to be separately controlled.

The second middle layer 17 has a structure in which a non-doped layer 17A and an n layer 17B are sequentially stacked from the second active layer 16. The non-doped layer 17A and the n layer 17B have a structure same as that of the non-doped layer 15A and the n layer 15B. That is, the non-doped layer 17A and the n layer 17B are made of a material same as that of the non-doped layer 15A and the n layer 15B except for impurities, and a thickness range is also the same as that of the non-doped layer 15A and the n layer 15B. The non-doped layer 17A is non-doped, and the n layer 17B is Si-doped. A reason why the n-side layer of the two second middle layers 17 is made non-doped is to improve carrier confinement in the first active layer 14 below the first middle layer 15.

A material of the second middle layer 17 is same as that of the first middle layer 15. The first middle layer 15 and the second middle layer 17 may be made of the same material. In addition, a thickness of the second middle layer 17 is also same as that of the first middle layer 15, and the first middle layer 15 and the second middle layer 17 may have the same thickness. However, it is preferable to make it thinner than the first middle layer 15 and to have an In composition larger than that in the first middle layer 15. This is because the second active layer 16 that emits green light is more susceptible to thermal damage than the first active layer 14 that emits blue light, and an influence of the strain at an interface is larger.

The third active layer 18 has a structure in which a first strain relaxation layer 18A, a second strain relaxation layer 18B, and an SQW or MQW quantum well structure layer 18C are sequentially stacked. An emission wavelength of the quantum well structure layer 18C is red and is 590 nm to 700 nm. The quantum well structure layer 18C has a structure in which a barrier layer made of InGaN and a well layer made of InGaN are alternately stacked for 1 to 7 pairs. The number of pairs is more preferably 1 to 5, and still more preferably 1 to 3. In addition, the number of pairs is preferably equal to or less than that of the quantum well structure layer 16B of the second active layer 16, and more preferably less than that of the quantum well structure layer 16B of the second active layer 16.

The first strain relaxation layer 18A has a structure same as that of the strain relaxation layer 16A of the second active layer 16. It is sufficient that a wavelength corresponding to band edge energy in a well layer of the first strain relaxation layer 18A is shorter than the emission wavelength of the quantum well structure layer 16B, and is, for example, 400 nm to 460 nm.

The second strain relaxation layer 18B has a wavelength corresponding to band edge energy in a well layer of the second strain relaxation layer 18B that is shorter than the emission wavelength of the quantum well structure layer 18C and that is longer than the wavelength corresponding to the band edge energy in the well layer of the first strain relaxation layer 18A. For example, it is 510 nm to 570 nm. The others are same as the first strain relaxation layer 18A.

A difference between the wavelength corresponding to the band edge energy in the well layer of the first strain relaxation layer 18A and the wavelength corresponding to the band edge energy in the well layer of the second strain relaxation layer 18B and a difference between the wavelength corresponding to the band edge energy in the well layer of the second strain relaxation layer 18B and the emission wavelength of the quantum well structure layer 18C are preferably 40 nm to 100 nm.

It is preferable to set a ratio of the thickness of the first active layer 14 to a thickness of the third active layer 18 or a ratio of the thickness of the second active layer 16 to the thickness of the third active layer 18 to be 30% or less. Strain in the quantum well structure layer 18C can be more efficiently relaxed.

In this way, when the first strain relaxation layer 18A and the second strain relaxation layer 18B are provided, the strain can be relaxed in stages, and the strain in the quantum well structure layer 18C stacked thereon can be effectively relaxed. As a result, a quality of the well layer of the quantum well structure layer 18C can be improved.

Note that, in the third active layer 18, the strain is relaxed in two stages by the first strain relaxation layer 18 A and the second strain relaxation layer 18B, and the strain may be relaxed in three or more stages by providing three or more strain relaxation layers. In the second active layer 16, a plurality of strain relaxation layers 16A may be provided to relax the strain in stages.

A strain relaxation layer may also be provided in the first active layer 14 in the same manner. In this case, a growth temperature for the strain relaxation layer is, for example, 800° C. to 900° C.

The electron blocking layer 21 is a semiconductor layer provided on the third active layer 18, and is a layer for blocking electrons injected from the n layer 11 in order to efficiently confine the electrons in the first active layer 14, the second active layer 16, and the third active layer 18. The electron blocking layer 21 may be a single layer of GaN or AlGaN, or may have a structure in which two or more of AlGaN, GaN, and InGaN are stacked, or a structure in which the above materials are stacked with only the composition ratio changed. Alternatively, the electron blocking layer 21 may have a superlattice structure. A thickness of the electron blocking layer 21 is preferably 5 nm to 50 nm, and more preferably 5 nm to 25 nm. A Mg concentration in the electron blocking layer 21 is preferably 1×10¹⁹ cm⁻³ to 100×10¹⁹ cm⁻³.

The p layer 22 is a semiconductor layer provided on the electron blocking layer 21, and includes a first layer and a second layer sequentially from the electron blocking layer 21. The first layer is preferably p-GaN or p-InGaN. A thickness of the first layer is preferably 10 nm to 500 nm, more preferably 10 nm to 200 nm, and still more preferably 10 nm to 100 nm. A Mg concentration in the first layer is preferably 1×10¹⁹ cm⁻³ to 100×10¹⁹ cm⁻³. The second layer is preferably p-GaN or p-InGaN. A thickness of the second layer is preferably 2 nm to 50 nm, more preferably 4 nm to 20 nm, and still more preferably 6 nm to 10 nm. A Mg concentration in the second layer is preferably 1×10²⁰ cm⁻³ to 100×10²⁰ cm⁻³.

A groove having a depth reaching the n layer 11 is provided in a predetermined region in the p layer 22. This groove is for providing the n electrode 23.

The n electrode 23 is an electrode provided on the n layer 11 exposed on a bottom surface of the groove. When the substrate 10 is made of a conductive material, the n electrode 23 may be provided on a back surface of the substrate 10 without providing the groove. A material of the n electrode 23 is, for example, Ti/Al or V/Al.

The p electrode 24 is an electrode provided on the p layer 22. A material of the p electrode 24 is preferably a material that has a high reflectance of light at the emission wavelength and has low contact resistance with respect to the p layer 22. For example, Ag, Ni/Au, Co/Au, ITO/Ni/Al, Rh, or Ru. Among light emitted from the first active layer 14, the second active layer 16, and the third active layer 18, light directed toward the p layer 22 is reflected by the p electrode 24 and goes toward the substrate 10.

### 2. Setting of Thickness of Each Layer

Red light emitted from the third active layer 18 includes light emitted toward the substrate 10 and light emitted toward the p layer 22 (opposite to the substrate 10) and directed toward the substrate 10 after being reflected by the p electrode 24, causing interference. The same applies to green light emitted from the second active layer 16 and blue light emitted from the first active layer 14. In the light emitting element according to the first embodiment, an element structure in which a light output is controlled by the interference of the light is set for light emission colors of blue, green, and red. Specifically, the settings are as follows.

First, thicknesses a0 to a3 are defined. The thickness a1 is a total film thickness of the electron blocking layer 21 and the p layer 22. The thickness a 2 is a total film thickness of the second middle layer 17, the third active layer 18, the electron blocking layer 21, and the p layer 22. The thickness a3 is a total film thickness of the first middle layer 15, the second active layer 16, the second middle layer 17, the third active layer 18, the electron blocking layer 21, and the p layer 22.

In the first embodiment, by setting the thicknesses a1 to a3, amplification and attenuation due to the interference of the light are controlled for each of red light, green light, and blue light, and the balance of the light output is controlled. Therefore, white light can be emitted by mixing the colors.

The thicknesses a1 to a3 can be adjusted by adjusting the first middle layer 15, the second middle layer 17, and the p layer 22. In addition, the thicknesses a1 to a3 may also be adjusted by adjusting the strain relaxation layer 16A of the second active layer 16, and the first strain relaxation layer 18A and the second strain relaxation layer 18B of the third active layer 18.

Generally, since red and green have light emission efficiency lower than that of blue, only red and green may be amplified. In addition, since red has the lowest light emission efficiency among the three colors, only red may be amplified. In this case, an amplification factor is, for example, 50% to 100%, preferably 70% to 100%, and more preferably 80% to 100%. Here, the amplification factor is 100% when the light output reaches the maximum due to the interference, and 0% when the light output takes a midpoint between the maximum value and the minimum value.

Generally, since blue has light emission efficiency higher than that of red and green, only blue may be attenuated. In this case, an attenuation factor is, for example, 60% to 100%, preferably 70% to 100%, and more preferably 80% to 100%. Here, the attenuation factor is 100% when the light output reaches the minimum due to the interference, and 0% when the light output takes a midpoint between the maximum value and the minimum value.

Generally, since red has light emission efficiency lower than that of green, the amplification factor for green may be lower than the amplification factor for red. For example, red may be se to an amplification factor of 60% to 100%, preferably 70% to 100%, and more preferably 80% to 100%, green may be se to an amplification factor 0% to 70%, preferably 0% to 50%, and more preferably 0% to 30%, and blue may be se to an attenuation factor of 60% to 100%, preferably 70% to 100%, and more preferably 80% to 100%.

The thicknesses a1 to a3 are set, for example, as follows. Optical lengths of the first active layer 14, the second active layer 16, and the third active layer 18 are expressed as m1×λn1, m2×λn2, and m3×λn3, respectively. λn1, λn2, and λn3 are values obtained by dividing the emission wavelength of the first active layer 14, second active layer 16, and third active layer 18 by an average refractive index of the layer above these active layers. At this time, when the thicknesses a1 to a3 are set to satisfy the following expressions, each light emission is amplified.

$$( m 3 - 0.1 ) \times λ n 3 < a 1 < ( m 3 + 0.1 ) \times λ n 3 \qquad ( 1 )$$

$$( m 2 - 0.1 ) \times λ n 2 < a 2 < ( m 2 + 0.1 ) \times λ n 2 \qquad ( 2 )$$

$$( m 1 - 0.1 ) \times λ n 1 < a 3 < ( m 1 + 0.1 ) \times λ n 1 \qquad ( 3 )$$

In the expressions (1) to (3), m≈0.2, 0.7, 1.2, . . . . Here, “≈” means that an error of about 0.1 is allowed for the value of m. For example, m≈0.7 means a range of about 0.6 to 0.8.

Note that, in a case of making settings such that the light output is attenuated due to the interference effect, it is sufficient to set m≈0.5, 1.0, 1.5, . . . in the expressions (1) to (3).

The first active layer 14, the second active layer 16, and the third active layer 18 are arranged in the order away from a reflective surface of the p electrode 24. Therefore, a relationship between the optical lengths of the first active layer 14, the second active layer 16, and the third active layer 18 is necessarily m1×λn1>m2×λn2>m3×λn3. In addition, since the emission colors of the first active layer 14, the second active layer 16, and the third active layer 18 are blue, green, and red, respectively, λn1<λn2<λn3. In a case of this stacking order of emission wavelengths, m1>m2>m3.

Since the interference of the light increases or decreases depending on a film thickness of a reflective film, in a case of amplifying the light from all active layers as much as possible, it is sufficient to keep m1=1.7±0.2, m2=1.2±0.2, and m3=0.7±0.2. In a case of combining amplification and attenuation, it is sufficient to adjust within a range of 0.1<m1, m2, m3<2.2.

In the first embodiment, the emission wavelengths of the first active layer 14, the second active layer 16, and the third active layer 18 are not limited to blue, green, and red, that is, it is not limited to λn1<λn2<λn3. For example, when λn1>λn2>λn3, m1≈<m2≈<m3. It is sufficient to set the values of m1, m2, and m3 according to the emission wavelength of each active layer, and to control the amplification or attenuation in light output due to the interference of the light.

### 3. Operation of Light Emitting Element

Next, an operation of the light emitting element according to the first embodiment will be described. In the light emitting element according to the first embodiment, when a voltage is applied between the p electrode 24 and the n electrode 23, blue, green, and red light can be emitted at the same time from the first active layer 14, the second active layer 16, and the third active layer 18. Since the light output of each color can be adjusted by the interference of the light, white can be obtained by mixing the colors.

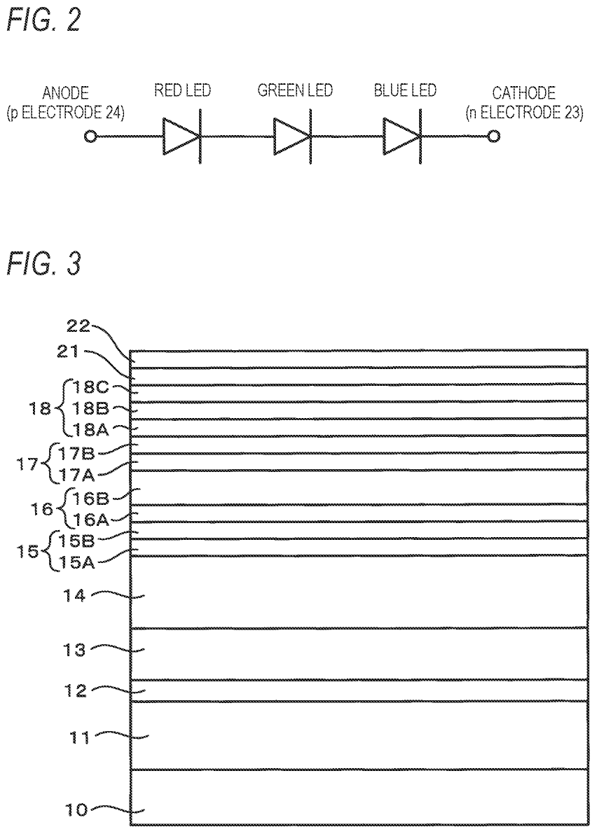

FIG. 2 shows an equivalent circuit of the light emitting element according to the first embodiment. As shown in FIG. 2, the light emitting element according to the first embodiment has a structure in which blue, green, and red LEDs are connected in series, and white light can be emitted with one element.

### 4. Process for Producing Light Emitting Element

Next, a process for producing the light emitting element according to the first embodiment will be described with reference to the drawings.

First, the substrate 10 is prepared, and the substrate is subjected to a heat treatment by adding hydrogen, nitrogen, and, if necessary, ammonia.

Next, a buffer layer is formed on the substrate 10, and the n layer 11, the ESD layer 12, the base layer 13, the first active layer 14, the first middle layer 15, the second active layer 16, the second middle layer 17, the third active layer 18, the electron blocking layer 21, and the p layer 22 are sequentially formed on the buffer layer (see FIG. 3). The preferred growth temperature for each layer is as follows.

The growth temperature for the first active layer 14 is preferably 700° C. to 950° C. The crystal quality can be improved and the light emission efficiency can be increased. The first active layer 14 includes a well layer and a barrier layer, and the well layer and the barrier layer may be formed at the same temperature or may be formed at different temperatures within the above temperature range. When the temperatures are different, it is preferable that the growth temperature for the well layer is lower than the growth temperature for the barrier layer.

The growth temperature for the first middle layer 15 is preferably 700° C. to 1000° C. This is for preventing thermal damage to the first active layer 14. When the temperature is lower than 700° C., pits and point defects due to threading dislocations are likely to occur. The growth temperature is more preferably 800° C. to 950° C., and still more preferably 850° C. to 950° C.

The growth temperature for the second active layer 16 is preferably 650° C. to 950° C. The crystal quality can be improved and the light emission efficiency can be increased. The second active layer 16 includes a well layer and a barrier layer, and the well layer and the barrier layer may be formed at the same temperature or may be formed at different temperatures within the above temperature range. When the temperatures are different, it is preferable that the growth temperature for the well layer is lower than the growth temperature for the barrier layer. In addition, the growth temperature for the second active layer 16 is preferably lower than the growth temperature for the first active layer 14.

The growth temperature for the second middle layer 17 is preferably in a range same as that of the growth temperature for the first middle layer 15. However, the growth temperature for the second middle layer 17 is preferably lower than the growth temperature for the first middle layer 15. This is because the second active layer 16 that emits green light is more susceptible to thermal damage than the first active layer 14 that emits blue light, and an influence of the strain at an interface is larger.

The growth temperature for the third active layer 18 is preferably 500° C. to 950° C. The crystal quality can be improved and the light emission efficiency can be increased. The third active layer 18 includes a well layer and a barrier layer, and the well layer and the barrier layer may be formed at the same temperature or may be formed at different temperatures within the above temperature range. When the temperatures are different, it is preferable that the growth temperature for the well layer is lower than the growth temperature for the barrier layer. In addition, the growth temperature for the third active layer 18 is preferably lower than the growth temperature for the second active layer 16.

The growth temperature for the electron blocking layer 21 is preferably 750° C. to 1000° C. This is for preventing thermal damage to the first active layer 14, the second active layer 16, and the third active layer 18. The growth temperature is more preferably 750° C. to 950° C., and still more preferably 800° C. to 900° C.

The growth temperature for the p layer 22 is preferably 650° C. to 1000° C. The growth temperature is more preferably 700° C. to 950° C., and still more preferably 750° C. to 900° C.

Here, the thicknesses of the first middle layer 15, the second middle layer 17, the electron blocking layer 21, and the p layer 22 are set to control the balance of the light output of the red light, the green light, and the blue light by the interference of the light.

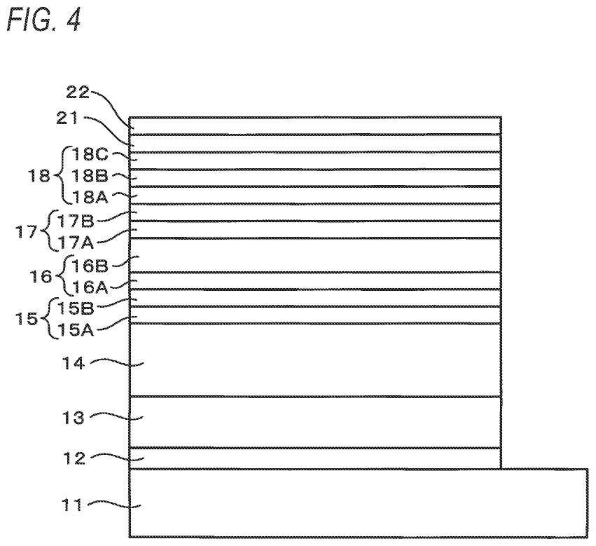

Next, a partial region on a surface of the p layer 22 is dry-etched until it reaches the n layer 11 to form the groove (see FIG. 4). Then, the n electrode 23 is formed on the exposed n layer 11, and the p electrode 24 is formed on the p layer 22. With the above, the light emitting element according to the first embodiment is produced.

### 5. Various Modifications

The light emitting element according to the first embodiment includes three active layers, i.e., the first active layer 14, the second active layer 16, and the third active layer 18. Alternatively, the present invention is applicable to any structure having two or more active layers with different emission wavelengths. In addition, the emission color is not limited to blue, green, or red, but may be any color as long as the emission wavelengths are different. For example, it may have two active layers of blue and yellow, or it may have four active layers of blue, green, red, and purple or yellow. In addition, the stacking order of two or more different active layers does not necessarily have to be such that the substrate side has a short wavelength and the p layer side has a long wavelength, but may be in the reverse order or may be random.

### REFERENCE SIGNS LIST

10: substrate
11: n layer
12: ESD layer
13: base layer
14: first active layer
15: first middle layer
16: second active layer
17: second middle layer
18: third active layer
21: electron blocking layer
22: p layer
23: n electrode
24: p electrode
15A, 17A: non-doped layer
15B, 17B: n layer
16A: strain relaxation layer
16B, 18C: quantum well structure layer
18A: first strain relaxation layer
18B: second strain relaxation layer

What is claimed is:

1. A light emitting element, which is a flip-chip type light emitting element comprising a group III nitride semiconductor, comprising:
a substrate;
an n layer that is provided over the substrate and comprises an n-type group III nitride semiconductor;
a first active layer that is provided over the n layer and has a predetermined emission wavelength;
a middle layer that is provided over the first active layer and comprises a group III nitride semiconductor having an n-type impurity concentration of 1×10¹⁸ cm⁻³ or less;
a second active layer that is provided over the middle layer and has an emission wavelength different from the emission wavelength of the first active layer;
a p layer that is provided over the second active layer and comprises a p-type group III nitride semiconductor; and
a p electrode that is provided over the p layer and is configured to reflect light, wherein
light emitted from the second active layer causes interference between light directed toward the substrate and light directed toward the p electrode and reflected by the p electrode, and the interference is controlled based on a thickness of the p layer,
light emitted from the first active layer causes interference between light directed toward the substrate and the light directed toward the p electrode and reflected by the p electrode, and the interference is controlled based on the thickness of the player and a thickness the middle layer, and
the thickness of the p layer and the thickness of middle layer are set such that at least one of the light emitted from the first active layer or the light emitted from the second active layer is amplified by the interference.

2. The light emitting element according to claim 1, wherein the middle layer comprises a group III nitride semiconductor containing In.

3. The light emitting element according to claim 1, wherein
the emission wavelength of the second active layer is longer than the emission wavelength of the first active layer,
the second active layer has a structure in which a strain relaxation layer having a quantum well structure and a thickness of a well layer adjusted so as not to emit light, and a light emitting layer having a quantum well structure and configured to emit light are sequentially stacked,
a wavelength corresponding to band edge energy of the well layer of the strain relaxation layer is set to be shorter than an emission wavelength of the light emitting layer, and
the thickness of the p layer, the thickness of the middle layer, and a thickness of the strain relaxation layer are set such that at least one of the light emitted from the first active layer or the light emitted from the second active layer is amplified by the interference.

4. The light emitting element according to claim 2, wherein
the emission wavelength of the second active layer is longer than the emission wavelength of the first active layer,
the second active layer has a structure in which a strain relaxation layer having a quantum well structure and a thickness of a well layer adjusted so as not to emit light, and a light emitting layer having a quantum well structure and configured to emit light are sequentially stacked,
a wavelength corresponding to band edge energy of the well layer of the strain relaxation layer is set to be shorter than an emission wavelength of the light emitting layer, and
the thickness of the p layer, the thickness of the middle layer, and a thickness of the strain relaxation layer are set such that at least one of the light emitted from the first active layer or the light emitted from the second active layer is amplified by the interference.

5. The light emitting element according to claim 1, wherein the middle layer has a structure in which a non-doped layer comprising a non-doped group III nitride semiconductor and an n layer comprising a n-type group III nitride semiconductor are sequentially stacked.

6. The light emitting element according to claim 2, wherein the middle layer has a structure in which a non-doped layer comprising a non-doped group III nitride semiconductor and an n layer comprising a n-type group III nitride semiconductor are sequentially stacked.

7. A method for producing a light emitting element which is a flip-chip type light emitting element comprising a group III nitride semiconductor, comprising:
an n layer forming step of forming an n layer comprising an n-type group III nitride semiconductor over a substrate;
a first active layer forming step of forming a first active layer having a predetermined emission wavelength over the n layer;
a middle layer forming step of forming a middle layer comprising a group III nitride semiconductor having an n-type impurity concentration of 1×10¹⁸ cm⁻³ or less over the first active layer;
a second active layer forming step of forming a second active layer having an emission wavelength different from the emission wavelength of the first active layer over the middle layer;
a p layer forming step of forming a p layer comprising a p-type group III nitride semiconductor over the second active layer; and
a p electrode forming step of forming, over the p layer, a p electrode configured to reflect light, wherein
light emitted from the second active layer causes interference between light directed toward the substrate and light directed toward the p electrode and reflected by the p electrode, and the interference is controlled based on a thickness of the p layer,
light emitted from the first active layer causes interference between light directed toward the substrate and light directed toward the p electrode and reflected by the p electrode, and the interference is controlled based on the thickness of the player and a thickness the middle layer, and
the thickness of the p layer and the thickness of middle layer are set such that at least one of the light emitted from the first active layer or the light emitted from the second active layer is amplified by the interference.

8. The method for producing a light emitting element according to claim 7, wherein the middle layer comprises a group III nitride semiconductor containing In.

9. The method for producing a light emitting element according to claim 7, wherein
the emission wavelength of the second active layer is longer than the emission wavelength of the first active layer,
the second active layer is formed by sequentially stacking a strain relaxation layer having a quantum well structure and a thickness of a well layer adjusted so as not to emit light, and a light emitting layer having a quantum well structure and configured to emit light,
a wavelength corresponding to band edge energy of the well layer of the strain relaxation layer is set to be shorter than an emission wavelength of the light emitting layer, and
the thickness of the player, the thickness of the middle layer, and a thickness of the strain relaxation layer are set such that at least one of the light emitted from the first active layer or the light emitted from the second active layer is amplified by the interference.

10. The method for producing a light emitting element according to claim 8, wherein
the emission wavelength of the second active layer is longer than the emission wavelength of the first active layer,
the second active layer is formed by sequentially stacking a strain relaxation layer having a quantum well structure and a thickness of a well layer adjusted so as not to emit light, and a light emitting layer having a quantum well structure and configured to emit light,
a wavelength corresponding to band edge energy of the well layer of the strain relaxation layer is set to be shorter than an emission wavelength of the light emitting layer, and
the thickness of the p layer, the thickness of the middle layer, and a thickness of the strain relaxation layer are set such that at least one of the light emitted from the first active layer or the light emitted from the second active layer is amplified by the interference.

11. The method for producing a light emitting element according to claim 7, wherein the middle layer is formed by sequentially stacking a non-doped layer comprising a non-doped group III nitride semiconductor and an n layer comprising a n-type group III nitride semiconductor.

12. The method for producing a light emitting element according to claim 8, wherein the middle layer is formed by sequentially stacking a non-doped layer comprising a non-doped group III nitride semiconductor and an n layer comprising a n-type group III nitride semiconductor.
